(19) United States
(12) Patent Application Publication
(10) Pub. No.: US 2013/0251447 A1
(43) Pub. Date: Sep. 26, 2013

(54) STARTING MATERIAL AND PROCESS FOR PRODUCING A SINTERED JOIN

(71) Applicants: Thomas Kalich, Victoria (AU); Daniel Wolde-Giorgis, Filderstadt (DE); Andrea Feiock, Pliezhausen (DE); Robert Kolb, Gross-Umstadt (DE)

(72) Inventors: Thomas Kalich, Victoria (AU); Daniel Wolde-Giorgis, Filderstadt (DE); Andrea Feiock, Pliezhausen (DE); Robert Kolb, Gross-Umstadt (DE)

(73) Assignee: ROBERT BOSCH GMBH, Stuttgart (DE)

(21) Appl. No.: 13/880,709

(22) PCT Filed: Mar. 29, 2011
(86) PCT No.: PCT/EP2011/054835

§ 371 Date: Apr. 19, 2013

(30) Foreign Application Priority Data
Oct. 20, 2010 (DE) 10 2010 042 702.0
Oct. 20, 2010 (DE) 10 2010 042 721.7

(51) Int. Cl. H05K 13/04; B23K 35/02

(52) U.S. Cl. CPC H05K 13/0465; B23K 35/0244
USPC 403/270; 75/255; 75/252; 75/228; 228/248.1

(57) ABSTRACT

The present invention relates to a starting material for producing a sintered connection. In order to avoid the formation of cracks in the joining partners in the case of fluctuating thermal loading, the starting material comprises second particles 20 in addition to metallic first particles 10, wherein the second particles 20 at least proportionately contain a particle core material which has a coefficient of thermal linear expansion α at 20° C. which is less than the coefficient of thermal linear expansion α at 20° C. of the metal or of the metals of the first particles in metallic form, and wherein the D₅₀ value of the second particles 20 is greater than or equal to half the D₅₀ value of the first particles 10 and less than or equal to two times the D₅₀ value of the first particles 10. In addition, the present invention relates to a corresponding sintered connection 100′, to an electronic circuit 70 and also to a process for forming a thermally and/or electrically conductive sintered connection.

### BACKGROUND OF THE INVENTION

The invention relates to a sintered bond, a starting material for producing it and a process for the production thereof, and also an electronic circuit containing the sintered bond.

Power electronics are used in many fields of technology. Especially in electrical or electronic appliances in which large currents flow, the use of power electronics is indispensible. The currents necessary in power electronics lead to thermal stressing of the electrical or electronic components present therein. Further thermal stress is caused by the use of such electrical or electronic appliances in places of operation having a temperature which is significantly above room temperature and may also change continually. Examples which may be mentioned are control instruments in the automobile sector which are arranged directly in the engine compartment.

In particular, many joins between power semiconductors or integrated circuits (ICs) among one another and also to support substrates are even today subject to long-term temperature stresses up to 175 degrees Celsius.

Joining of electrical or electronic components, for example on a support substrate, is usually effected by means of a bonding layer. A bonding layer of this type is a solder bond.

Use is usually made of soft solders based on tin-silver or tin-silver-copper alloys. However, such bonding layers display, particularly at use temperatures close to the melting point, a decrease in electrical and mechanical properties which can lead to failure of the assembly.

Lead-containing solder bonds can be used at higher use temperatures than soft solder bonds. However, lead-containing solder bonds are greatly restricted in respect of their permissible industrial applications by legal obligations for reasons of environmental protection.

An alternative for use at elevated or high temperatures, in particular above 200 degrees Celsius, is lead-free hard solders. Lead-free hard solders generally have a melting point above 200° C. However, when hard solder is used for producing a bonding layer, only few electrical or electronic components which can withstand the high temperatures during melting of the hard solders come into question as join partners.

One way out is the low-temperature bonding technology (NTV) in which silver-containing sintered bonds can be produced even at significantly lower temperatures than the melting point. Here, a paste containing chemically stabilized silver particles and/or silver compounds is used instead of a solder. Under the sintering conditions, in particular at elevated temperature and applied pressure, the stabilizing constituents are burnt out and/or the silver compounds are decomposed so that the silver particles or liberated silver atoms come into direct contact with one another and with the material of the join partners. A high-temperature-stable bond can be formed by interdiffusion and/or diffusion even at significantly lower temperatures than the melting point. However, when such sintered bonds are subjected to temperature changes, thermomechanical stresses and even crack formation in semiconductor components or even in the support substrate can occur.

The document DE 102009000192 A1 describes a sintering material for producing a sintered bond which can be formed as a sintering paste and comprises metallic structure particles provided with an organic coating and also metallic and/or ceramic auxiliary particles which are not organically coated and do not liberate gas during the sintering process.

### SUMMARY OF THE INVENTION

The present invention provides a starting material for a sintered bond, which comprises metal-containing first particles and second particles, where the second particles contain, in particular, at least a proportion of a particle of core material whose coefficient of thermal expansion a at 20° C. is lower than the coefficient of thermal expansion a at 20° C. of the metal or metals of the first particles in metallic form and/or whose coefficient of thermal expansion a at 20° C. is ≦15·10⁻⁶ K⁻¹ and the D₅₀ of the second particles is greater than or equal to half the D₅₀ of the first particles and less than or equal to twice the D₅₀ of the first particles.

For the purposes of the present invention, the D₅₀ is the median of a particle size distribution, in particular of primary particles, in particular in accordance with DIN 53 206, which indicates the particle diameter, in particular primary particle diameter, above and below which the diameter of half of the particles is in each case and which corresponds to the diameter at which the cumulated distribution reaches the value 0.5. The D₅₀ of particles and in particular of mixtures of a plurality of different particles, e.g. first, second, third and/or fourth particles, can be determined, in particular, by means of electron microscopy, optionally in combination with energy-dispersive X-ray spectroscopy (EDX).

By the use of second particles which have a particle core material with a low coefficient of thermal expansion, the coefficient of thermal expansion α (CTE) of the starting material or of the sintered bonds produced therefrom can advantageously be significantly reduced. Experiments hitherto have shown that sintered bonds formed in this way can advantageously have a coefficient of thermal expansion α at 20° C. in the range from ≧3·10⁻⁶ K⁻¹ to ≦15·10⁻⁶ K⁻¹, for example from ≧3·10⁻⁶ K⁻¹ to ≦10·10⁻⁶ K⁻¹, in particular from ≧3·10⁻⁶ K⁻¹ to ≦7·10⁻⁶ K⁻¹. Sintered bonds having such a low coefficient of thermal expansion cannot be achieved by means of the conventionally used silver sintering pastes, which usually have a coefficient of thermal expansion α at 20° C. of about 19.5·10⁻⁶ K⁻¹, and are of particular interest for, in particular, semiconductor technology since here join partners are frequently joined together by means of sintered bonds which on the one hand, as in the case of chips, have a very low coefficient of expansion, for example about 3·10⁻⁶ K⁻¹, or on the other hand, for example in the case of metallic circuit substrates, have a very high coefficient of expansion, for example about 16.5·10⁻⁶ K⁻¹, which is one of the main causes for crack formation when subjected to changing temperatures. The second particles advantageously enable the coefficient of thermal expansion to be set so that it lies between the coefficients of thermal expansion of the join partners to be joined via the sintered layer, for example between 16.5·10⁻⁶ K⁻¹ (circuit substrate) and 3·10⁻⁶ K⁻¹ (chip). Thermomechanical stresses between the join partners and the sintered bond, which can lead to crack formation in the join partners in the event of temperature changes, can advantageously be reduced significantly in this way. The material costs can advantageously be reduced by the use of inexpensive second particles.

According to the present invention, it has been found that the particle size or particle size distribution of the first and second particles should not differ too greatly from one another in order to achieve optimal results, since an excessively high fines content of second particles can have an unfavorable effect on the sintering of the first particles and thus on the stability of the sintered microstructure, with an excessively high coarse content of second particles being able to lead to inhomogeneities and accordingly to macroscopic fluctuations in the materials properties, within the sintered bond.

Overall, sintered bonds having a significantly improved thermomechanical stability when subjected to temperature changes can thus advantageously be formed from the starting material of the invention.

For the purposes of the present invention, a starting material for a sintered bond can be a starting material which is used for producing a sintered bond, in particular for mechanical and electrical bonding of electrical and/or electronic components. The starting material of the invention can, for example, be a paste, a powder mixture or a sintering material preform.

For the purposes of the present invention, in particular, all elements of the alkali metal group, in particular Li, Na, K, Rb, Cs, and alkaline earth metal group, in particular Be, Mg, Ca, Sr, Ba, the transition metals, in particular Sc, Y, La, Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Hg, the lanthanides and the elements aluminum, gallium, indium, tin, thallium, lead and bismuth are considered to be metals.

For the purposes of the present invention, noble metals are the elements silver, gold, platinum, palladium, ruthenium, rhodium, osmium and iridium.

For the purposes of the present invention, silicon is considered to be a semimetal and not a metal.

Adjectives having the ending-containing, e.g. metal-containing, noble metal-containing, silver-containing and copper-containing, mean, for the purposes of the present invention, that at least one element of the element group given the ending-containing, for example one or more metals or one or more noble metals, or the element given the ending-containing, for example silver or copper, is present. Apart from the elemental form, in particular the metallic form, of the elements or element, for example elemental, i.e. metallic, silver, compounds of the elements or the element, for example silver carbonate, silver oxide and/or silver carboxylates, are therefore also encompassed.

For the purposes of the present invention, the term metallic refers, in particular, to a form in which metallic bonds are present between the atoms of one or more elements, in particular where the atoms form a lattice having freely mobile (delocalized) electrons.

In one embodiment, the particle core material is a chemically inert and physically stable material.

For the purposes of the present invention, a chemically inert material is a material which does not undergo any chemical reaction with the other materials of the starting material under the sintering conditions.

For the purposes of the present invention, a physically stable material is a material which does not display any phase transition, for example from solid to liquid (melting), under the sintering conditions.

In one embodiment, the D₅₀ of the second particles is greater than or equal to half the D₅₀ of the first particles and less than or equal to 1.5 times the D₅₀ of the first particles. In particular, the D₅₀ of the second particles can be greater than or equal to 0.75 times the D₅₀ of the first particles and less than or equal to 1.25 times the D₅₀ of the first particles. The thermomechanical stability of the sintered bond when subjected to temperature changes can advantageously be improved further in this way.

The D₅₀ of the first particles and/or second particles and the third particles described below can be, for example, in the range from ≧0.01 μm to ≦50 μm, in particular from ≧0.1 μm to ≦10 μm, for example from ≧1 μm to ≦7 μm. Particles having such a particle size distribution advantageously have a high specific surface area and therefore an increased reactivity. Thus, the necessary processing temperature and the process time for forming a sintered bond can advantageously be kept low.

If, for example, first particles having a D₅₀ of 3 μm are used, the second particles preferably have a D₅₀ in the range from ≧1.5 μm to ≦6 μm (from half to twice the D₅₀ of the first particles), for example from ≧1.5 μm to ≦4.5 μm (from half to 1.5 times the D₅₀ of the first particles), in particular from ≧2.25 μm to ≦3.75 μm (from 0.75 to 1.25 times the D₅₀ of the first particles).

In a further embodiment, the coefficient of thermal expansion a of the particle core material at 20° C. is ≦10·10⁻⁶ K⁻¹, in particular ≦7.5·10⁻⁶ K⁻¹, preferably ≦5·10⁻⁶K⁻¹. The coefficient of thermal expansion can thus advantageously be reduced more strongly and/or with a smaller amount of second particles.

In a further embodiment, the particle core material has a thermal conductivity λ_{20/50} at 20° C. and 50% atmospheric humidity of ≧15 Wm⁻¹ K⁻¹ or ≧25 Wm⁻¹ K⁻¹, preferably ≧50 Wm⁻¹ K⁻¹, in particular ≧100 Wm⁻¹ K⁻¹. This is particularly advantageous for increasing the power density of semiconductor chips.

In a further embodiment, the particle core material is selected from the group consisting of elemental silicon (Si), silicon oxide (SiO₂), silicon carbide (SiC), aluminum nitride (AlN), silicon nitride (Si₃N₄), aluminum oxide (Al₂O₃), metallic tungsten (W), metallic molybdenum (Mo), metallic chromium (Cr), metallic platinum (Pt), metallic palladium (Pd), boron carbide (BC), beryllium oxide (BeO), boron nitride (BN), preferably elemental silicon and silicon dioxide, silicon carbide, aluminum nitride, silicon nitride, aluminum oxide, and combinations thereof. These materials advantageously have a lower coefficient of thermal expansion, which, as mentioned above, is advantageous in order to avoid crack formation in the join partners. In addition, these materials are basically advantageously chemically inert during a thermal treatment of the starting material to form a sintered bond and, in a sintered bond which has been formed, are present in unchanged from within the metal matrix formed. In one embodiment, the second particles or at least the particle cores thereof can be composed of such a material. Particular preference is given to elemental silicon and/or silicon dioxide.

For example, the second particles can contain at least a proportion of elemental silicon and/or silicon dioxide. In particular, the second particles can have a particle core composed of elemental silicon and/or silicon dioxide, in particular elemental silicon. Elemental silicon and silicon dioxide have an extremely low coefficient of thermal expansion a (CTE) and have therefore been found to be particularly advantageous for, inter alia, reducing the coefficient of thermal expansion of the sintered bond. Even the addition of a small amount therefore advantageously enables a larger reduction in the coefficient of thermal expansion of the sintered bond than is the case for other additives to be achieved. In addition, elemental silicon and silicon dioxide advantageously have low Young's moduli, which can have an advantageous effect on the elasticity of the sintered bond. A reduction in the coefficient of thermal expansion of the sintered bond and the good elastic properties can in turn significantly reduce the thermomechanical stress between the sintered bond and the semiconductor component bonded thereto and thus the tendency for crack formation in the semiconductor component. Owing to the advantageous coefficients of expansion and Young's moduli of elemental silicon and silicon dioxide, a sintered bond composed of such a starting material can advantageously have a lower coefficient of expansion at the same or even a lower Young's modulus than a similar unfilled sintered bond, in particular one which has a correspondingly larger proportion of first particles instead of a proportion of second particles.

Both amorphous and crystalline, in particular polycrystalline, elemental silicon and/or silicon dioxide can in principle be used. The elemental silicon and/or silicon dioxide can in principle be used in all purities which can be obtained. In order to minimize the materials costs, it is possible to use, for example, raw silicon, for example silicon having a purity of ≧95%.

In a further embodiment, the particle core material is amorphous elemental silicon and/or amorphous silicon dioxide. Amorphous elemental silicon and amorphous silicon dioxide advantageously have a particularly low coefficient of thermal expansion and a low Young's modulus, with, in particular, the coefficient of expansion and the Young's modulus of amorphous elemental silicon being lower than that of crystalline elemental silicon and that of amorphous silicon dioxide being lower than that of crystalline silicon dioxide.

In a preferred embodiment, the particle core material is elemental silicon. For the purposes of the present invention, elemental silicon is preferably used since both its amorphous form compared to amorphous silicon dioxide and its crystalline form compared to crystalline silicon dioxide have a lower coefficient of expansion and a higher electrical conductivity and thermal conductivity. The use of elemental silicon therefore advantageously enables the coefficient of thermal expansion of the sintered bond to be significantly reduced, in particular with maintenance of good elastic properties.

The second particles can, in particular, each have a particle core having a coating applied thereto. The particle core is preferably composed of the particle core material, for example elemental silicon, silicon dioxide, silicon carbide, aluminum nitride, silicon nitride and/or aluminum oxide. The coating can be composed of a particle coating material which is different from the particle core material. If the particles are coated, the D₅₀ relates to the particle size including the coating.

In a further embodiment, the second particles are spherical, in particular essentially round, for example essentially ball-shaped, particles. Here, the term “essentially” means that small deviations from the ideal shape, in particular a spherical shape, for example by up to 15%, are encompassed. Avoidance of corners and edges advantageously enables excessive stresses and thus crack nuclei in the composite material to be avoided.

In a further embodiment, the first particles have a particle core with a first coating applied thereto and/or the second particles have a particle core with a second coating applied thereto.

The first and/or second coating and the third and/or further coating described below in each case advantageously encloses the particle cores essentially completely, but at least virtually completely. As a result, the coatings act firstly as a protective coating by means of which it can be ensured that the particles and the proportion of the material present in the respective coating remain chemically stable, which has an advantageous effect on the storage stability. In addition, agglomeration of the particles can be reduced or even avoided in this way. Furthermore, an in particular metal-containing, in particular metallic, coating, for example on the second, optionally the third and optionally the fourth particles, can improve the sintering of the coated particles, for example onto the first or other particles.

The coatings preferably make up a significantly smaller proportion of the particle volume than the particle cores. This has an advantageous effect on the sintering process and also the thermal and electrical properties of the starting material and of the sintered bond.

In a further embodiment, the first particles are noble metal-containing and/or copper-containing. As noble metal, particular preference is given to silver, gold, platinum and/or palladium. The first particles are preferably silver-containing.

In a further embodiment, the first particles contain, in particular, at least one metal, in particular at least one noble metal and/or copper, preferably silver, in metallic form and/or at least one organic or inorganic metal compound, in particular noble metal compound and/or copper compound, preferably silver compound, in particular a compound which can be converted into the metallic form of the at least one parent metal by a thermal treatment. The organic or inorganic metal compound can, for example, be selected from the group consisting of silver carbonate, silver oxide, silver lactate, silver stearate and combinations thereof. These compounds can advantageously be converted at high temperatures into the parent metal in metallic form.

In particular, the first particles can have a metal-containing, in particular noble metal-containing and/or copper-containing, for example silver-containing, particle core.

In one embodiment, at least part of the first particles have a particle core which contains at least one metal, in particular at least one noble metal and/or copper, preferably silver, in metallic form. For example, at least part of the first particles can be composed of at least one metal, in particular noble metal and/or copper, preferably silver, in metallic form.

In an alternative or additional embodiment, at least part of the first particles have a particle core which contains at least one organic or inorganic metal compound, in particular noble metal compound and/or copper compound, preferably silver compound, which, in particular, can be converted into the metallic form of the at least one parent metal by means of a thermal treatment.

In a specific embodiment, at least a first part of the first particles have a particle core which contains at least one metal, in particular at least one noble metal and/or copper, preferably silver, in metallic form and at least a second part of the first particles have a particle core which contains at least one organic or inorganic metal compound, in particular noble metal compound and/or copper compound, preferably silver compound, which can be converted into the metallic form of the at least one metal of the first part of the first particles by means of a thermal treatment.

As an alternative or in addition thereto, the first coating, for example of the first part of the first particles, can contain at least one organic or inorganic metal compound, in particular noble metal compound and/or copper compound, preferably silver compound, which, in particular, can be converted into the at least one parent metal in metallic form by a thermal treatment. The organic or inorganic metal compound can, here too, be selected, for example, from the group consisting of silver carbonate, silver oxide, silver lactate, silver stearate and combinations thereof. These compounds can advantageously be converted at high temperatures into the parent metal in metallic form.

As an alternative or in addition thereto, the first coating of the first particles or a further coating applied on top of the first coating of the first particles can contain a reducing agent by means of which a or the organic or inorganic metal compound, in particular noble metal compound and/or copper compound, preferably silver compound, can be reduced to the metallic form, for example at a temperature in the region of or optionally below the sintering temperature of the metallic form of the at least one parent metal.

As an alternative or in addition thereto, the second and/or third particles can also have a coating containing such reducing agents.

The proportion of reducing agent in the starting material is preferably selected so that it is present in a stoichiometric ratio to the organic or inorganic metal compound, in particular noble metal compound and/or copper compound, preferably silver compound, which is present in the starting material and is, in particular, to be reduced. A very high conversion of up to 99% or more can advantageously be achieved in this way.

As reducing agent, it is possible to use, for example, at least one alcohol from the group consisting of primary or secondary alcohols and/or at least one amine and/or formic acid and/or at least one fatty acid, in particular isostearic acid, stearic acid, oleic acid, lauric acid or a mixture of various fatty acids.

Overall, such reducing agent-containing first coatings can be applied in a simple manner to the first particles. In addition, the reducing agents mentioned display, in a thermal treatment of the starting material for forming a sintered bond, particularly good reducing behavior in respect of the organic or inorganic metal compounds or noble metal oxides present in the second coating of the second particles. Reducing agent-containing coatings enable the reducing agent to be advantageously distributed very uniformly and finely in the entire starting material. As a result, the sintering process within the starting material can proceed more uniformly and more quickly. This gives the advantage that a sintered bond produced from the starting material of the invention can have a very homogeneous sintered microstructure, in particular one having a high thermal and/or electrical conductivity. This effect can be reinforced further by the use of coatings which contain organic or inorganic metal compounds, in particular noble metal compounds and/or copper compounds, preferably silver compounds, corresponding to the first particles and are, for example, in direct contact with the reducing agent-containing coatings. The temperature at which the organic or inorganic metal compound is converted into the parent metallic form can advantageously be reduced here. This makes it possible for join partners joined via the sintered bond formed, for example electrical and/or electronic components of an electronic circuit, advantageously not to be subjected to high temperatures during formation of the sintered bond. Thus, heat-sensitive electrical and/or electronic components in electronic circuits, which due to the otherwise excessively high process temperatures could not be used in production of the bond, can be electrically and/or thermally contacted.

The second coating can be metal-containing, in particular noble metal-containing and/or copper-containing, preferably silver-containing. In one embodiment, the second coating contains at least one metal, in particular noble metal and/or copper, preferably silver, in metallic form. In another embodiment, the second coating contains at least one metal as an organic or inorganic metal compound, in particular noble metal compound and/or copper compound, preferably silver compound, which, in particular, can be converted into the metallic form, in particular of the at least one parent metal, in particular of the first particles, by a thermal treatment. The organic or inorganic metal compound can in this case also be selected for example from the group consisting of silver carbonate, silver oxide, silver lactate, silver stearate and combinations thereof. These compounds can advantageously be converted into the parent metal in metallic form at high temperatures.

As an alternative or in addition thereto, the second coating or a further coating applied on top of the second coating can contain a reducing agent by means of which the reduction of a or the organic or inorganic metal compound, in particular noble metal compound and/or copper compound, preferably silver compound, in particular of the metal/metals of the first particles, to the metallic form can be carried out, for example at a temperature in the region of or optionally below the sintering temperature of the metallic form of the at least one parent metal, in particular of the first particles.

In a further embodiment, the second coating contains at least one metal selected from the group consisting of silver, platinum, palladium, gold, tin and combinations thereof. The second coating preferably contains at least one of the metals of the first particles. In particular, the second coating can contain the same metals as the first particles, for example silver. The adhesion of the second particles in the starting material can advantageously be improved in this way. Since the layer thickness of the coating is preferably smaller than the radius of the particle cores, the coefficient of thermal expansion of the coating influences that of the sintered bond to a lesser extent than the coefficient of expansion of the particle core material. However, it can be advantageous to use platinum and/or palladium in the coating material in order to achieve further minimization of the coefficient of expansion of the sintering material.

Furthermore, the starting material can comprise third particles. The third particles, too, can have a particle core and optionally a third coating applied to the particle core. The third coating can be metal-containing, in particular noble metal-containing and/or copper-containing, preferably silver-containing. In one embodiment, the third coating contains at least one metal, in particular noble metal and/or copper, preferably silver, in metallic form. In another embodiment, the third coating contains at least one metal as an organic or inorganic metal compound, in particular noble metal compound and/or copper compound, preferably silver compound, in particular one which can be converted into the metallic form, in particular of the at least one parent metal, in particular of the first particles, by a thermal treatment. The organic or inorganic metal compound can, here too, be selected from, for example, the group consisting of silver carbonate, silver oxide, silver lactate, silver stearate and combinations thereof. These compounds can advantageously be converted at high temperatures into the parent metal in metallic form.

As an alternative or in addition thereto, the third coating or a further coating applied on top of the third coating can contain a reducing agent by means of which the reduction of a or the organic or inorganic metal compound, in particular noble metal compound and/or copper compound, preferably silver compound, in particular of the metal/metals of the first particles, to the metallic form can be carried out, for example at a temperature in the region of or optionally below the sintering temperature of the metallic form of the at least one parent metal, in particular of the first particles.

In a further embodiment, the third coating contains at least one metal selected from the group consisting of silver, platinum, palladium, gold and combinations thereof. The third coating preferably contains at least one of the metals of the first particles. In particular, the third coating can contain the same metals as the first particles, for example silver. The adhesion of the third particles in the starting material can advantageously be improved in this way. Since the layer thickness of the coating is preferably smaller than the radius of the particle cores, the coefficient of thermal expansion of the coating influences that of the sintered bond to a lesser extent than the coefficient of expansion of the particle core material. However, it can be advantageous to use platinum and/or palladium in the coating material in order to achieve further minimization of the coefficient of expansion of the sintering material.

The third particles preferably contain at least a proportion of at least one metal, for example tin, in particular in metallic form, which is converted by a thermal treatment, in particular in the region of or optionally below the sintering temperature of the metallic form of the metal/metals of the first particles, into an alloy comprising the metal or metals of the first particles, in particular an alloy which has a lower melting point than the metal or metals of the first particles in metallic form. In particular, the particle cores of the third particles can be formed therefrom. The processing temperature for formation of the sintered bond can advantageously be reduced further in this way. Furthermore, the alloys can be present as ductile phases within the sintered microstructure formed, as a result of which the sintered bonds formed are less susceptible to thermal and/or mechanical stresses, in particular changing stresses. Furthermore, tin, for example, has a low melting point, so that the particles composed of tin melt earlier during a thermal treatment of the starting material and bring about adhesive contact between all particles present in the starting material. This advantageously promotes the diffusion processes occurring during the sintering process.

In a further embodiment, the starting material comprises, based on the total weight of the constituents, ≧5% by weight, in particular ≧10% by weight, for example ≧20% by weight or ≧25% by weight, of second particles, in particular where the sum of the constituents of the starting material is 100% by weight. Such an amount of second particles makes it possible to achieve a significant reduction in the coefficient of thermal expansion of the sintered bond, in particular compared to a corresponding sintered bond which comprises a further proportion of first particles instead of the second particles.

In a further embodiment, the starting material comprises, based on the total weight of the constituents, ≦60% by weight, in particular ≦50% by weight, of second particles, in particular where the sum of the constituents of the starting material is 100% by weight. Such an amount of second particles in the starting material advantageously makes it possible to still produce a sintered layer which bonds or adheres well.

If the starting material further comprises third particles, the starting material comprises, based on the total weight of the constituents, a total of ≦60% by weight, in particular ≦50% by weight, of second and third particles, in particular where the sum of the constituents of the starting material is 100% by weight.

In a further embodiment, the starting material comprises, based on the total weight of the constituents, a total of from ≧5% by weight or ≧10% by weight to ≦60% by weight, in particular from ≧10% by weight or ≧20% by weight or ≧25% by weight to ≦50% by weight, of second particles or of second and third particles, in particular where the sum of the constituents of the starting material is 100% by weight.

In a further embodiment, the starting material comprises, based on the total weight of the constituents, from ≧25% by weight to ≦80% by weight of first particles, in particular where the sum of the constituents of the starting material is 100% by weight.

Furthermore, the starting material can comprise at least one solvent. For example, the starting material can comprise, based on the total weight of the constituents, from ≧5% by weight or ≧10% by weight to ≦25% by weight, in particular from ≧10% by weight to ≦20% by weight, of solvents, in particular where the sum of the constituents of the starting material is 100% by weight.

Furthermore, the starting material can comprise at least one or more additives, for example reducing agents and/or oxidants.

For example, the starting material can comprise a total of from ≧25% by weight to ≦80% by weight of first particles and from ≧5% by weight to ≦60% by weight of second particles or of second and third particles, in particular where the sum of the constituents of the starting material is 100% by weight. Furthermore, the starting material can comprise from ≧5% by weight to ≦25% by weight of solvents and/or from ≧0.1% by weight to ≦10% by weight of additives, in particular where the sum of the constituents of the starting material is 100% by weight.

The starting material is preferably provided as a paste. The viscosity of the paste can be set by means of the solvent added. It is likewise advantageous to provide the starting material in the form of a pellet or as a shaped body, in particular as a flat shaped body. In this case, the paste-like starting material is introduced into a mold or applied to a film. The solvent is subsequently driven off from the starting material by means of a thermal treatment. Here, it is possible to provide, in particular, a solvent which can be driven off without leaving a residue at a temperature in the region of or below the sintering temperature of the starting material. The starting material formed in this way can also be manufactured in the form of a large sheet which is then cut into small shaped bodies for the particular application.

The first, second, third and further coatings of the first, second and/or third particles present in the starting material can in principle be applied by means of known coating processes. These can be found in the known technical literature. Examples which may be mentioned are chemical and physical coating processes such as chemical or physical vapor deposition.

As regards further features and advantages of the starting material of the invention, explicit reference is made here to the information provided in connection with the use according to the invention, the sintered bond of the invention, the electronic circuit of the invention, the process of the invention and the figures.

The present invention further provides for the use of elemental silicon, silicon oxide, silicon carbide, aluminum nitride, silicon nitride, aluminum oxide, metallic tungsten, metallic molybdenum, metallic chromium, metallic platinum, metallic palladium, boron carbide, beryllium oxide, boron nitride and combinations for reducing the coefficient of thermal expansion a of a starting material for a sintered bond or of a sintered bond, in particular in a sintering paste, a sintering powder or a sintering material preform.

As regards further features and advantages of the use according to the invention, explicit reference is made here to the information provided in connection with the starting material of the invention, the sintered bond of the invention, the electronic circuit of the invention, the process of the invention and the figures.

The present invention further provides a sintered bond composed of a starting material of the invention.

Experiments hitherto have shown that a sintered bond formed from such a starting material can advantageously have a coefficient of thermal expansion α at 20° C. in the range from ≧3·10⁻⁶ K⁻¹ to ≦15·10⁻⁶ K⁻¹, for example from ≧3·10⁻⁶ K⁻¹ to ≦10·10⁻⁶ K⁻¹, in particular from ≧3·10⁻⁶ K⁻¹ to ≦7·10⁻⁶ K⁻¹. Sintered bonds having such a low coefficient of thermal expansion cannot be achieved by means of the conventionally used silver sintering pastes, which usually have a coefficient of thermal expansion α at 20° C. of about 19.5·10⁻⁶ K⁻¹, and are of particular interest for, in particular, semiconductor technology since here join partners are frequently joined together by means of sintered bonds which on the one hand, as in the case of chips, have a very low coefficient of expansion, for example about 3·10⁻⁶ K⁻¹, or on the other hand, for example in the case of metallic circuit substrates, have a very high coefficient of expansion, for example about 16.5·10⁻⁶ K⁻¹, which is one of the main causes for crack formation when subjected to changing temperatures. The second particles advantageously enable the coefficient of thermal expansion to be set so that it lies between the coefficients of thermal expansion of the join partners to be joined via the sintered layer, for example between 16.5·10⁻⁶ K⁻¹ (circuit substrate) and 3·10⁻⁶ K⁻¹ (chip). Thermomechanical stresses between the join partners and the sintered bond, which can lead to crack formation in the join partners in the event of temperature changes, can advantageously be reduced significantly in this way. The sintered bond produced from the starting material of the invention can also advantageously have a comparatively high thermal conductivity, measured at 20° C. and 50% atmospheric humidity, of ≧100 Wm⁻¹ K⁻¹. This is particularly advantageous for increasing the power density of semiconductor chips. The addition of elemental silicon in particular can counter crack formation to a great extent, since elemental silicon has a particularly advantageous effect on the elasticity of the sintered bond because of its low Young's modulus. In addition, the sintered bonds of the invention can advantageously achieve electrical conductivities which are only slightly below that of pure silver.

The proportion of second particles is preferably set in such a way that the coefficient of thermal expansion α_{S} of the sintered bond layer at 20° C. is less than or equal to the coefficient of thermal expansion α_{F1} of a first join partner (joined by means of the sintered bond) at 20° C. and greater than or equal to the coefficient of thermal expansion α_{F2} of a second join partner (joined by means of the sintered bond) at 20° C.

In one embodiment, the proportion of second particles in the starting material is set in such a way that the coefficient of thermal expansion α_{S} of the sintered bond or of the middle region of the sintered bond is in a range: α_{F2}+0.2·(α_{F1}−α_{F2})≦α_{S}≦α_{F2}+0.8·(α_{F1}−α_{F2}), in particular α_{F2}+0.25·(α_{F1}−α_{F2})≦α_{S}≦α_{F2}+0.75·(α_{F1}−α_{F2}), where α_{F1} is the coefficient of expansion of a first join partner and α_{F2} is the coefficient of expansion of a second join partner and α_{F1}≧α_{F2}. Crack formation in the event of changing temperatures can advantageously be significantly reduced in this way.

In a preferred embodiment, the proportion of second particles in the sintered bond increases stepwise or continuously from a boundary layer with a first join partner having a greater coefficient of expansion in the direction of a boundary layer with a second join partner having a smaller coefficient of thermal expansion, or, conversely, the proportion of second particles in the sintered bond decreases stepwise or continuously from a boundary layer with a first join partner having a smaller coefficient of expansion in the direction of a boundary layer with a join partner having a greater coefficient of thermal expansion. The differences between the coefficients of thermal expansion between boundary layers which are in contact with one another and thus crack formation in the event of temperature changes can be minimized particularly advantageously in this way. Such a gradient can, for example, be produced by application of a plurality of sintering paste layers having a decreasing or increasing proportion of second particles, for example by means of a printing process.

As regards further features and advantages of the electronic circuit of the invention, explicit reference is made here to the information provided in connection with the starting material of the invention, the sintered bond of the invention, the use according to the invention, the process of the invention and the figures.

The present invention further provides an electronic circuit having a sintered bond according to the invention.

As regards further features and advantages of the electronic circuit of the invention, explicit reference is made here to the information provided in connection with the starting material of the invention, the sintered bond of the invention, the process of the invention and the figures.

The invention further provides a process for forming a thermally and/or electrically conductive sintered bond. Here, a starting material of the invention is used as starting material.

The starting material can here be applied between two join partners. Preferred join partners are electrical and/or electronic components having contact points which are brought into direct physical contact with the starting material.

The proportion of second particles is preferably set in such a way that the coefficient of thermal expansion α_{S} of the sintered bond layer at 20° C. is less than or equal to the coefficient of thermal expansion α_{F1} of a first join partner at 20° C. and greater than or equal to the coefficient of thermal expansion α_{F2} of a second join partner at 20° C.

In one embodiment, the proportion of second particles is set in such a way that the coefficient of thermal expansion α_{S} of the sintered bond or of the middle region of the sintered bond is in a range: α_{F2}+0.2·(α_{F1}−α_{F2})≦α_{S}≦α_{F2}+0.8·(α_{F1}−α_{F2}), in particular α_{F2}+0.25·(α_{F1}−α_{F2})≦α_{S}≦α_{F2}+0.75·(α_{F1}−α_{F2}), where α_{F1} is the coefficient of expansion of a first join partner and α_{F2} is the coefficient of expansion of a second join partner and α_{F1}≧α_{F2}. Crack formation in the event of temperature changes can advantageously be significantly reduced in this way.

In a preferred embodiment, the proportion of second particles in the sintered bond increases stepwise or continuously from a boundary layer with a first join partner having a greater coefficient of expansion in the direction of a boundary layer with a second join partner having a smaller coefficient of thermal expansion, or, conversely, the proportion of second particles in the sintered bond decreases stepwise or continuously from a boundary layer with a first join partner having a smaller coefficient of expansion in the direction of a boundary layer with a join partner having a greater coefficient of thermal expansion. The differences between the coefficients of thermal expansion of boundary layers which are in contact with one another and thus crack formation in the event of temperature changes can be minimized particularly advantageously in this way.

Such a gradient can, for example, be produced by application of a plurality of sintering paste layers having a decreasing or increasing proportion of second and/or third particles, for example by means of a printing process. Here, the starting material can be applied in the form of a printing paste to the contact points, for example by means of screen printing or stenciling. Application by injection or dispensing processes is likewise possible.

A further possibility is to arrange the starting material as shaped body between the join partners.

The sintered bond is subsequently formed by thermal treatment of the starting material.

For example, a processing temperature of ≦400° C., preferably ≦300° C., in particular ≦250° C., can be provided. The sintering process is optionally carried out under pressure in order to improve the sintering process. A pressure of ≦10 MPa, preferably ≦4 MPa or even ≦1.6 MPa, particularly preferably ≦0.8 MPa, is provided as process pressure. If the reducing agent has not been used in a stoichiometric amount but instead in excess, excess reducing agent can be burnt out completely if sufficient oxygen is supplied, for example under an air atmosphere. Join partners having contact points composed of a noble metal, for example gold, silver or an alloy of gold or silver, are preferably provided.

In an alternative possible variant of the process of the invention, the sintered bond is formed in vacuo and/or under a nitrogen atmosphere. Since in this case excess reducing agent cannot be burnt, a starting material in which the proportion of the organic or inorganic metal compound, in particular the metal compound to be reduced, present in the starting material is present in the second coating in a stoichiometric ratio to the proportion of the reducing agent present in the starting material should be provided. During the thermal treatment, the reducing agent is accordingly completely consumed. In addition, the organic or inorganic metal compound is completely converted into the metallic form. In this process variant, join partners having a contact point which does not contain noble metal and is instead composed, for example, of copper can advantageously also be provided. This enables inexpensive electrical and/or electronic components also to be employed.

As regards further features and advantages of the process of the invention, explicit reference is hereby made to the information provided in connection with the starting material of the invention, the use according to the invention, the sintered bond of the invention, the electronic circuit of the invention and the figures.

### BRIEF DESCRIPTION OF THE DRAWINGS

Further advantages and advantageous embodiments of the subject matter of the invention are illustrated by the drawings and described in the following description. It should be noted that the drawings merely have descriptive character and are not intended to restrict the invention in any way. The drawings show

FIG. 1 a schematic plan view of particles of a starting material according to the invention for a sintered bond according to a first embodiment which comprises first and second particles;

FIG. 2 a schematic plan view of particles of a starting material according to the invention for a sintered bond according to a second embodiment which comprises first, second and third particles;

FIG. 3a-f schematic cross sections through embodiments of first particles;

FIG. 4a-e schematic cross sections through embodiments of second particles;

FIG. 5a, b schematic cross sections through embodiments of third particles;

FIG. 6 a schematic cross section through a first embodiment of an electronic circuit according to the invention;

FIG. 7 a schematic cross section through a second embodiment of an electronic circuit according to the invention; and

FIG. 8 a schematic cross section through a sintering oven in the production of a sintered bond or electronic circuit according to the invention.

In the figures, identical components and components having the same function are characterized by the same reference numerals.

### DETAILED DESCRIPTION

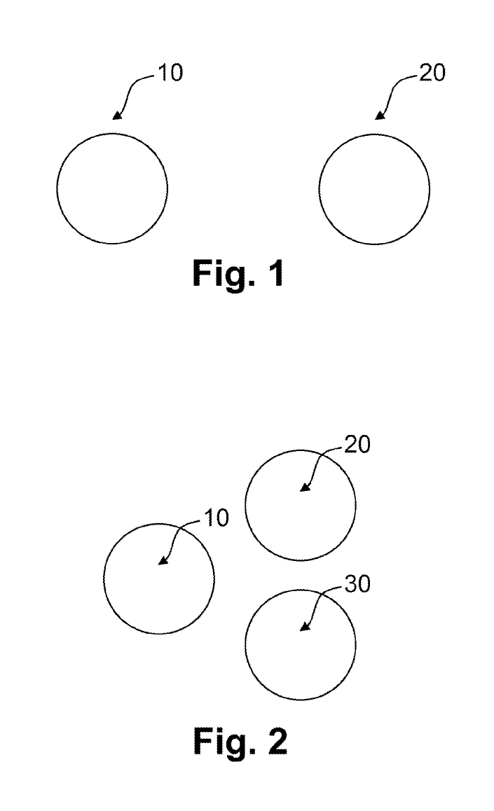

FIG. 1 schematically shows first particles 10 and second particles 20 which are provided in a first embodiment of a starting material according to the invention for a sintered bond. FIG. 1 shows that the first particles 10 and second particles 20 have essentially the same sizes. The first particles 10 and second particles 20 preferably have as similar a particle size distribution as possible. In particular, the D₅₀ of the second particles 20 is greater than or equal to half the D₅₀ of the first particles 10 and less than or equal to twice the D₅₀ of the first particles 10. Such a relationship between the particle size distribution of the first particles 10 and second particles 20 has been found to be particularly advantageous since a higher fine content of second particles can have an adverse effect on the sintering of the first particles, with a higher coarse content of second particles being able to lead to great inhomogeneities and accordingly to macroscopic fluctuations of the materials properties within the sintered bond.

FIG. 2 schematically shows first particles 10, second particles 20 and third particles 30 which are provided in a second embodiment of a starting material according to the invention for a sintered bond. In the embodiment shown, said particles are also essentially equal in size and have a similar particle size distribution.

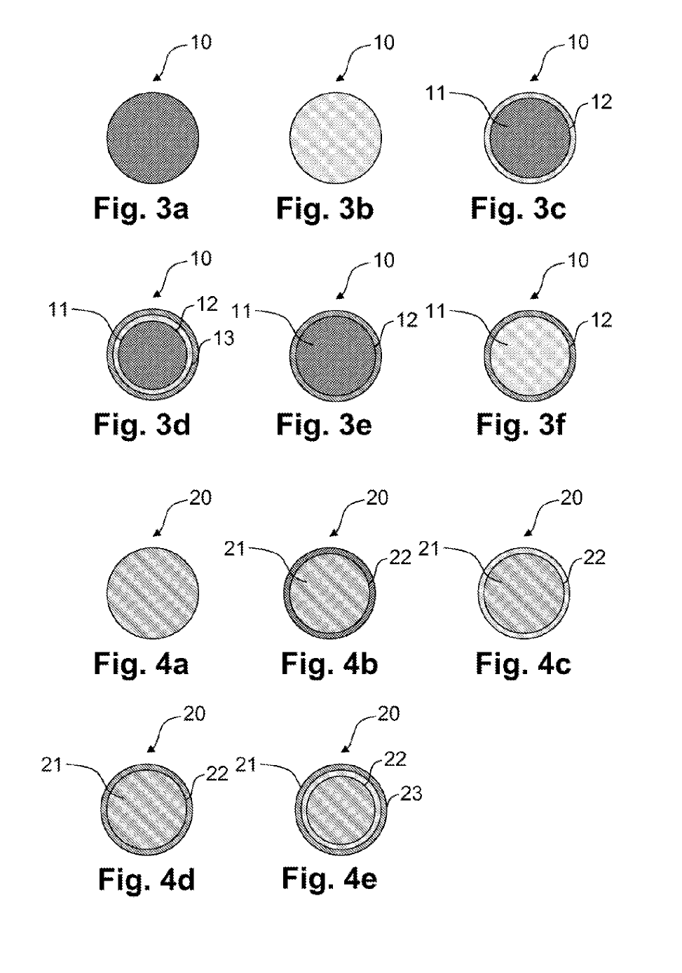

The starting material can, in the embodiments illustrated in FIGS. 1 and 2, contain metal-containing first particles 10 of one or more of the embodiments shown in FIGS. 3a to 3f. For example, the first particles 10 can be noble metal-containing and/or copper-containing, in particular silver-containing, particles. In the interests of simplicity, the figures are explained below for the example of silver-containing first particles 10.

FIG. 3a shows a first particle 10 which is composed of silver in metallic form.

FIG. 3b shows a first particle 10 which is composed of an organic or inorganic silver compound, for example silver carbonate (Ag₂CO₃) and/or silver oxide (Ag₂O, AgO), which can be converted into metallic silver by a thermal treatment.

FIG. 3c shows a first particle 10 which has a particle core 11 composed of silver in metallic form and a first coating 12 which is applied thereto and is composed of an organic or inorganic silver compound, for example silver carbonate and/or silver oxide, which can be converted into metallic silver by a thermal treatment.

FIG. 3d shows a first particle 10 which has a particle core 11 composed of silver in metallic form and a first coating 12 which is applied thereto and is composed of an organic or inorganic silver compound, for example silver carbonate and/or silver oxide, which can be converted into metallic silver by a thermal treatment. In addition, the particle 10 shown in FIG. 3d has a further coating 13 which is applied on top of the first coating 12 and contains a reducing agent, for example a fatty acid, by means of which the reduction of the organic or inorganic silver compound to metallic silver can be carried out.

FIG. 3e shows a first particle 10 which has a particle core 11 composed of silver in metallic form and a first coating 12 which is applied thereto and contains reducing agent, for example fatty acid, where the reduction of an organic or inorganic silver compound, for example silver carbonate and/or silver oxide, to metallic silver can be carried out by means of the reducing agent. The organic or inorganic silver compound can be a constituent of another first particle 10, second particle 20 or third particle 30.

FIG. 3f shows a first particle 10 which has a particle core 11 composed of an organic or inorganic silver compound, for example silver carbonate and/or silver oxide, which can be converted into metallic silver by a thermal treatment. In addition, the first particle 10 has a first coating 12 which is applied to the particle core 11 and contains a reducing agent, for example fatty acid, by means of which the reduction of the organic or inorganic silver compound to metallic silver from metallic silver can be carried out.

FIG. 4a shows a second particle 20 whose particle core is composed of a material which has a low coefficient of thermal expansion α at 20° C. of ≦10·10⁻⁶ K⁻¹, in particular ≦7.5·10⁻⁶ K⁻¹, preferably 5·10⁻⁶ K⁻¹. The material here can be, for example, elemental silicon, silicon oxide, silicon carbide, aluminum nitride, silicon nitride, aluminum oxide, metallic tungsten, metallic molybdenum, metallic chromium, metallic platinum, metallic palladium, boron carbide, beryllium oxide and/or boron nitride. In addition, these materials advantageously have a good thermal conductivity λ_{20/50} at 20° C. and 50% atmospheric humidity of ≧50 Wm⁻¹ K⁻¹, in particular ≧100 Wm⁻¹ K⁻¹, which is particularly advantageous for increasing the power density of semiconductor chips.

FIG. 4b shows a second particle 20 which has a particle core 21 composed of a material with a low coefficient of thermal expansion α at 20° C. of ≦10·10⁻⁶ K⁻¹, in particular of ≦7.5·10⁻⁶ K⁻¹, preferably 5·10⁻⁶ K⁻¹. A second coating 22 composed of silver, platinum or palladium in metallic form is in this case applied to the particle core 21.

FIG. 4c shows a second particle 20 which has a particle core 21 composed of a material with a low coefficient of thermal expansion α at 20° C. of ≦10·10⁻⁶ K⁻¹, in particular of ≦7.5·10⁻⁶ K⁻¹, preferably 5·10⁻⁶ K⁻¹. In addition, the particle 20 has a second coating 22 which is applied to the particle core and is composed of an organic or inorganic silver compound, for example silver carbonate and/or silver oxide, which can be converted into metallic silver by a thermal treatment.

FIG. 4d shows a second particle 20 which has a particle core 21 composed of a material with a low coefficient of thermal expansion α and a second coating 22 which is applied thereto and contains a reducing agent, for example fatty acid, by means of which the reduction of an organic or inorganic silver compound, for example silver carbonate and/or silver oxide, which is a constituent of another first particle 10, second particle 20 or third particle 30 to metallic silver can be carried out.

FIG. 4e shows a second particle 20 which has a particle core 21 composed of a material with a low coefficient of thermal expansion and a second coating 22 which is applied thereto and is composed of an organic or inorganic silver compound, for example silver carbonate and/or silver oxide, which can be converted into metallic silver by a thermal treatment. In addition, the particle 20 shown in FIG. 4e has a further coating 23 which is applied on top of the second coating 22 and contains a reducing agent, for example a fatty acid, by means of which the reduction of the organic or inorganic silver compound to metallic silver can be carried out.

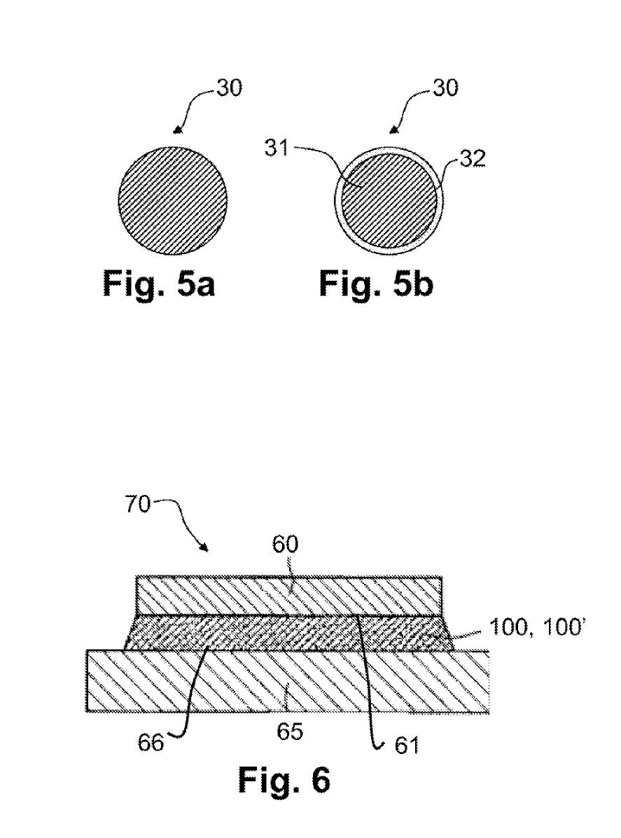

FIG. 5a shows a third particle 30 which contains a metal, for example tin, which forms an alloy with silver as a result of a thermal treatment and/or has a melting point lower than that of metallic silver.

FIG. 5b shows a third particle 30 which has a particle core 31 composed of a metal, for example tin, which forms an alloy with silver as a result of a thermal treatment and/or has a melting point lower than that of metallic silver. In addition, the third particle shown in FIG. 5b has a third coating 32 which is applied to the particle core 31 and is composed of an organic or inorganic silver compound, for example silver carbonate and/or silver oxide, which can be converted into metallic silver by a thermal treatment.

FIG. 6 shows a first embodiment of an electronic circuit 70 which has a substrate 65 having at least one contact point 66. The contact point 66 of the substrate 65 is joined to a contact point 61 of a chip 60 by means of a sintered bond 100′ produced from a starting material 100 according to the invention.

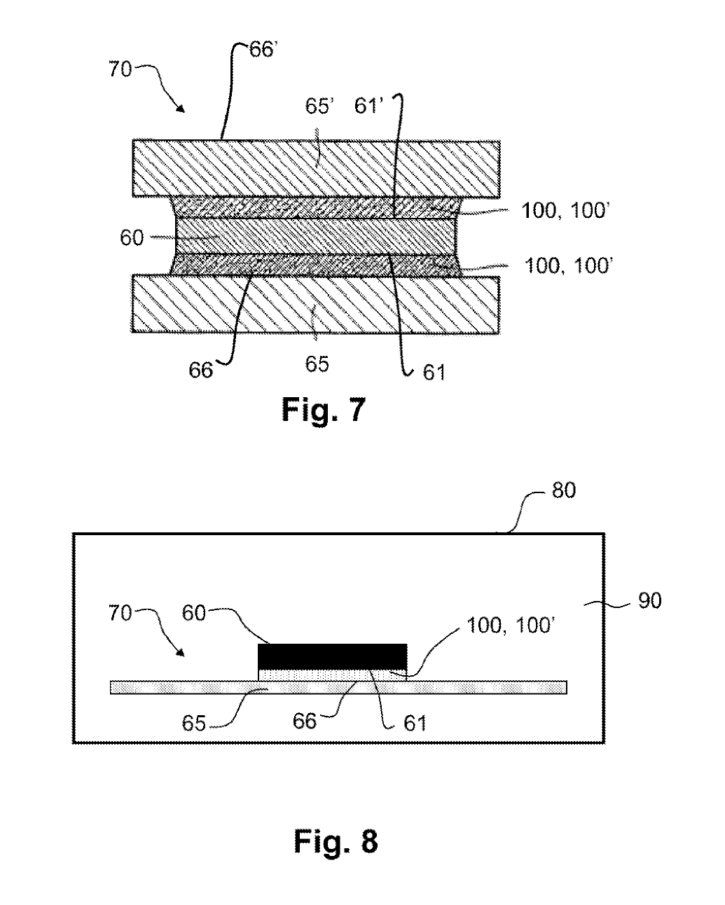

FIG. 7 shows a second embodiment of an electronic circuit 70 which has a first substrate 65 having at least one contact point 66. The first contact point 66 of the first substrate 65 is joined to a first contact point 61 of a chip 60 by means of a first sintered bond 100 produced from a starting material 100 according to the invention. In turn, a second contact point 61′ of the chip 60 is joined to a contact point 66′ of a second substrate 65′ by means of a second sintered bond 100 which is likewise produced from the starting material 100 of the invention.

FIG. 8 shows a sintering oven 80 and also an electronic circuit 70 arranged in a process space 90 of the sintering oven 80. The electronic circuit 70 has a substrate 65 having at least one first contact point 66 composed of copper. A chip 60 having at least one second contact point 61 composed of a silver alloy is arranged on the substrate 65. Between the at least first contact point 66 composed of copper and the at least second contact point 61 composed of the silver alloy, a starting material 100 according to the invention has been applied as paste. The starting material 100 contains a proportion of a mixture of first particles 10 and second particles 20 corresponding to FIGS. 1 to 4e.

To form a sintered bond 100′ between the at least first contact point 66 of the substrate 65 and the at least second contact point 61 of the chip 60, the electronic circuit 70 with the starting material 100 is subjected to a thermal treatment. To carry out the thermal treatment, the sintering oven 80 contains a heating device within the process space 90. A vacuum or a protective gas atmosphere, for example, is present in the process space 90 during the thermal treatment of the starting material 100.

The starting material 100 is, for example, applied as a paste in which the first particles 10 and second particles 20 and optionally the third particles 30 are present in dispersed form.

The thermal treatment of the electronic circuit 70 triggers physical and/or chemical reaction processes in the starting material 100. Here, reducing agent optionally present, for example a fatty acid, can react with an optional organic or inorganic silver compound, for example silver carbonate and/or silver oxide, to form metallic silver at a temperature in the region of or optionally below the sintering temperature of silver. A largely complete conversion into silver can be achieved by means of the above-described embodiments of the particles containing silver compounds.

The metal-containing first particles 10 sinter together to form an electrically conductive sintered microstructure. Here, the second particles or the particle cores thereof behave as inert material. The coatings 12, 13, 22, 23, 31, 32 described in connection with FIGS. 3c to 5b can aid sintering within the sintered microstructure. After formation of the sintered bond 100′, the elemental material of the second particles 20 is present as a fine dispersion within the metallic silver matrix of the sintered micro-structure 100′. In addition, third particles 30 corresponding to FIGS. 5a and 5b can also be cosintered in the silver matrix.

The third particles 30, for example composed of tin, present, optionally as a mixture with the first and second particles 10 and 20, in the starting material 100 melt at an earlier juncture during the thermal treatment and aid contact of the material of all particles 10, 20, 30 present in the starting material 100. In addition, the third particles 30 can form alloys with the constituents of the first particles 10 and optionally particle coatings 12, 13, 22, 32. These alloys are then present as ductile phases within the silver matrix formed in the sintered microstructure.

Contacting of the first and second contact points 61, 66 of the substrate or of the chip 65 likewise occurs by means of the sintered bond 100′ formed. Contacting of the first contact point 66 composed of copper during the thermal treatment is possible without corrosion phenomena since contacting is carried out in vacuo or under a protective gas atmosphere. As a result, a non-precious material, for example composed of copper, also remains free of oxidation products during the thermal treatment to form the sintered bond 100′.

1. A starting material (100) for a sintered bond (100′), which comprises
metal-containing first particles (10) and
second particles (20),
characterized in that the second particles (20) contain at least a proportion of a particle core material (21) whose coefficient of thermal expansion α at 20° C. is smaller than the coefficient of thermal expansion α at 20° C. of the metal or metals of the first particles (10) in metallic form,
and
the D₅₀ of the second particles (20) is greater than or equal to half the D₅₀ of the first particles (10) and less than or equal to twice the D₅₀ of the first particles (10).

2. The starting material as claimed in claim 1, wherein the coefficient of thermal expansion α of the particle core material (21) at 20° C. is ≦10·10⁻⁶ K⁻¹.

3. The starting material as claimed in claim 1, wherein the D₅₀ of the second particles (20) is greater than or equal to half the D₅₀ of the first particles and less than or equal to 1.5 times the D₅₀ of the first particles (10).

4. The starting material as claimed in claim 1, wherein the particle core material (21) has a thermal conductivity λ_{20/50} at 20° C. and 50% atmospheric humidity of ≧15 Wm⁻¹ K⁻¹.

5. The starting material as claimed in claim 1, wherein the particle core material (21) is a chemically inert and physically stable material.

6. The starting material as claimed in claim 1, wherein the particle core material (21) is selected from the group consisting of elemental silicon, silicon oxide, silicon carbide, aluminum nitride, silicon nitride, aluminum oxide, metallic tungsten, metallic molybdenum, metallic chromium, metallic platinum, metallic palladium, boron carbide, beryllium oxide, boron nitride and combinations.

7. The starting material as claimed in claim 1, wherein the particle core material (21) is elemental silicon and/or silicon dioxide.

8. The starting material as claimed in claim 1, wherein the second particles (20) have a particle core (21) with a second coating (22) applied thereto, where the second coating (22) comprises at least one metal selected from the group consisting of silver, platinum, palladium, gold, tin and combinations thereof.

9. The starting material as claimed in claim 1, wherein the second particles (20) are spherical.

10. The starting material as claimed in claim 1, wherein the first particles (10) are noble metal-containing and/or copper-containing.

11. The starting material as claimed in claim 1, wherein the first particles (10) have a particle core (11) with a first coating (12) applied thereto.

12. The starting material as claimed in claim 1, wherein the starting material (100) comprises, based on the total weight of the constituents, ≧5% by weight, and/or ≦60% by weight, of second particles (20) and from ≧25% by weight to ≦80% by weight of first particles (10).

13. A sintered bond (100′) composed of a starting material as claimed in claim 1.

14. The sintered bond (100′) as claimed in claim 13, wherein the proportion of second particles (20) is set in such a way that the coefficient of thermal expansion α_{S} of the sintered bond (100′) or of the middle region of the sintered bond (100′) is in the range: α_{F2}+0.2·(α_{F1}−α_{F2})≦α_{S}≦α_{F2}+0.8·(α_{F1}−α_{F2}) where α_{F1} is the coefficient of expansion of the first join partner (65) and α_{F2} is the coefficient of expansion of the second join partner and α_{F1}≧α_{F2}.

15. An electronic circuit (70) having a sintered bond (100′) as claimed in claim 13.

16. A process for forming a thermally and/or electrically conductive sintered bond (100′), in which a starting material (100) for the sintered bond (100′) as claimed in claim 1 is provided, which comprises the following steps:
provision of the starting material (100),
formation of the sintered bond (100′) by a thermal treatment of the starting material (100).

17. The starting material as claimed in claim 1, wherein the coefficient of thermal expansion a of the particle core material (21) at 20° C. is ≦5·10⁻⁶ K⁻¹.

18. The starting material as claimed in claim 1, wherein the particle core material (21) has a thermal conductivity λ_{20/50} at 20° C. and 50% atmospheric humidity of ≧100 Wm⁻¹ K⁻¹.

19. The starting material as claimed in claim 1, wherein the particle core material (21) is selected from the group consisting of elemental silicon, silicon dioxide, silicon carbide, aluminum nitride, silicon nitride, aluminum oxide, metallic molybdenum, metallic chromium, metallic platinum, metallic palladium and combinations thereof.

20. The starting material as claimed in claim 1, wherein the particle core material (21) is amorphous elemental silicon and/or amorphous silicon dioxide.

21. The starting material as claimed in claim 1, wherein the first particles (10) contain silver and/or at least one organic or silver compound, where the silver compound can be converted into at least one parent metal in metallic form by a thermal treatment.

22. The starting material as claimed in claim 1, wherein the starting material (100) comprises, based on the total weight of the constituents, ≧25% by weight, and/or ≦50% by weight, of second particles (20) and from ≧25% by weight to ≦80% by weight of first particles (10).

23. The sintered bond (100′) as claimed in claim 13, wherein the proportion of second particles (20) in the sintered bond (100′) increases stepwise or continuously from a boundary layer (66) with the first join partner (65) having the greater coefficient of expansion α_{F1} in the direction of a boundary layer (61) with the second join partner (60) having the smaller coefficient of thermal expansion α_{F2}.
